(19) United States
(12) Patent Application Publication
(10) Pub. No.: US 2004/0224506 A1
(43) Pub. Date: Nov. 11, 2004

(54) Methods of forming metal layers using metallic precursors

(76) Inventors: Kyung-In Choi, Gyeonggi-do (KR); Sang-Bum Kang, Seoul (KR); Byung-Hee Kim, Seoul (KR); Gil-Heyun Choi, Gyeonggi-do (KR)

Correspondence Address: MYERS BIGEL SIBLEY & SAJOVEC, PO BOX 37428, RALEIGH, NC, 27627, US

(21) Appl. No.: 10/863,244

(22) Filed: Jun. 8, 2004

Related U.S. Application Data
(62) Division of application No. 10/196,814, filed on Jul. 17, 2002.

(30) Foreign Application Priority Data
Jul. 19, 2001 (KR) 2001-43526
Mar. 29, 2002 (KR) 2002-17479

(51) Int. Cl. C30B 1/00; H01L 21/36; H01L 21/44; H01L 21/20

(52) U.S. Cl. 438/681

(57) ABSTRACT

Methods of forming metal layers include techniques to form metal layers using atomic layer deposition techniques that may be repeated in sequence to build up multiple atomic metal layers into a metal thin film. The methods include forming a metal layer by chemisorbing a metallic precursor comprising a metal element and at least one non-metal element that is ligand-bonded to the metal element, on a substrate. The metal element may include tantalum. The chemisorbed metallic precursor is then converted into the metal layer by removing the at least one non-metal element from the metallic precursor through ligand exchange. This removal of the non-metal element may be achieved by exposing the chemisorbed metallic precursor to an activated gas that is established by a remote plasma, which reduces substrate damage. The activated gas may be selected from the group consisting of H₂, NH₃, SiH₄ and Si₂H₆ and combinations thereof. These steps may be performed at a temperature less than about 650° C.

This application is a divisional application of co-pending U.S. patent application Ser. No. 10/196,814, filed Jul. 17, 2002, which claims priority from Korean Patent Application Nos. 2001-43526, filed on Jul. 19, 2001 and 2002-17479, filed on Mar. 29, 2002, the contents of which are hereby incorporated herein by reference as if set forth in their entirety.

### FIELD OF THE INVENTION

The present invention relates to methods of forming thin films and metal layers and, more particularly, to methods of forming thin films and metal layers using metallic precursors.

### BACKGROUND OF THE INVENTION

Many semiconductor devices are required to operate at high speeds and have large storage capacity. To achieve these goals, semiconductor technologies have been developed to improve the integration density, reliability and the speed of semiconductor devices.

There are typically strict requirements for metal layers that are used for metal lines on a semiconductor device. In addition, to increase the density of devices formed on a semiconductor substrate, the metal layer is formed as a multi-layer structure. The metal layer is mainly formed by depositing aluminum or tungsten. However, the specific resistance of aluminum is about 2.8×10⁻⁸ μΩm and the specific resistance of tungsten is about 5.5×10⁻⁸ μΩm, so they are typically not suitable as a multi-layer structure. For this reason, copper, which has relatively low specific resistance and good electromigration characteristics is typically used as a metal layer.

Copper has a high mobility in silicon and silicon dioxide (SiO2). In addition, when copper is reacted with silicon and silicon dioxide, the copper is easily oxidized. Accordingly, it is preferred to suppress the oxidization of copper by using a barrier metal layer.

A titanium nitride layer is widely used as the barrier metal layer. However, the titanium nitride layer is not suitable as a barrier metal layer for copper because the titanium nitride layer is required to have a thickness above 30 nm to restrain the mobility of copper. Since the titanium nitride layer has a resistance proportional to the thickness thereof and high reactivity, the resistance is highly increased when the titanium nitride layer has a thickness above 30 nm.

For this reason, a tantalum nitride layer is suggested for the barrier metal layer, because a tantalum nitride layer can restrain the mobility of copper even when the tantalum nitride layer is thin and has low resistance. Examples of tantalum nitride layers that can be used as barrier metal layers are disclosed in U.S. Pat. No. 6,204,204 (issued to Paranjpe et. al.), U.S. Pat. No. 6,153,519 (issued to Jain et. al.), and U.S. Pat. No. 5,668,054 (issued to Sun et. al.).

According to the disclosure in U.S. Pat. No. 5,668,054, the tantalum nitride layer is deposited through a chemical vapor deposition process by using terbutylimido-tris-diethylamido-tantalum ((NEt₂)₃Ta═Nbu^{t}, hereinafter simply referred to as “TBTDET”) as a reactant. The process is carried out at a temperature above 600° C. If the process is carried out at a temperature of about 500° C., the specific resistance of tantalum nitride layer may exceed 10,000 μΩcm. In addition, since the above process is carried out at a relatively high temperature, the semiconductor device can be thermally damaged. Further, it is typically difficult to achieve a tantalum nitride layer having superior step coverage when a chemical vapor deposition process is used.

Recently, an atomic layer deposition (ADL) process has been suggested as a substitute for the chemical vapor deposition process. The atomic layer deposition process can be carried out at a relatively low temperature as compared with a conventional thin film forming process and can achieve superior step coverage. Examples of the atomic layer deposition process for depositing tantalum nitride are disclosed in U.S. Pat. No, 6,203,613 (issued to Gates) and in an article by Kang et al., entitled Plasma-Enhanced Atomic Layer Deposition of Tantalum Nitrides Using Hydrogen Radicals as a Reducing Agent, Electrochemical and Solid-State Letters, 4(4) C 17-19 (2001). As described in the Kang et al. article, a tantalum nitride layer having a specific resistance about 400 μΩcm, can be formed by an atomic layer deposition process using TBTDET. The deposition is carried out at a temperature of about 260° C. Accordingly, a thin film having a low specific resistance can be formed at a relatively low temperature. In addition, a hydrogen radical obtained by a plasma-enhanced process is used as a reducing agent. Therefore, a power source is applied into a chamber when the deposition is carried out. For this reason, the process described by Kang et al. has process parameters that are influenced by the power source applied to the chamber. Thus, while the Kang et al. process can be used to form a thin film having low specific resistance at a relatively low temperature, the process parameters, which include control of the power source, are added. Moreover, because the Kang et al. process requires that the power source be applied directly to a predetermined portion of the chamber to which a semiconductor substrate is placed, the semiconductor substrate can be damaged by the power source.

Accordingly, notwithstanding the disclosed techniques to form tantalum nitride layers, there continues to be a need for improved methods that require less complex process parameters.

### SUMMARY OF THE INVENTION

Methods of forming metal layers according to embodiments of the present invention include techniques to form metal layers using atomic layer deposition techniques that may be repeated in sequence to build up multiple atomic metal layers into a metal thin film. This metal thin film may be used as a barrier metal layer on integrated circuit substrates. According to first embodiments of the present invention, methods of forming a metal layer include chemisorbing a metallic precursor comprising a metal element and at least one non-metal element that is ligand-bonded to the metal element, on a substrate. The metal element may include tantalum. The chemisorbed metallic precursor is then converted into the metal layer by removing the at least one non-metal element from the metallic precursor through ligand exchange. This removal of the non-metal element may be achieved by exposing the chemisorbed metallic precursor to an activated gas that is established by a remote plasma, which reduces substrate damage. The activated gas may be selected from the group consisting of H₂, NH₃, SiH₄ and Si₂H₆ and combinations thereof. These steps may be performed at a temperature of less than about 650° C.

According to preferred aspects of these embodiments, the chemisorbing step includes exposing the substrate to a metallorganic precursor comprising tantalum or exposing the substrate to a tantalum halide precursor. The metallorganic precursor may be a tantalum amine derivative. The chemisorbing step may also include removing reactants that have not be chemisorbed to the substrate by exposing the substrate to an inert gas.

Methods of forming metal layers according to additional embodiments of the present invention include chemisorbing a first metallic precursor comprising a metal element and at least one non-metal element that is ligand-bonded to the metal element, on a substrate and then converting the chemisorbed first metallic precursor into a first atomic metal layer by removing the at least one non-metal element from the first metallic precursor. The first atomic metal layer is then built up with additional atomic metal layers. The build up process includes chemisorbing a second metallic precursor that comprises the metal element and the at least one non-metal element that is ligand-bonded to the metal element, on the first atomic metal layer. The chemisorbed second metallic precursor is then converted into a second atomic metal layer by removing the at least one non-metal element from the second metallic precursor. This sequence of steps may be repeated many times to form a metal thin film that may be used as a barrier metal layer within an integrated circuit device.

### BRIEF DESCRIPTION OF THE DRAWINGS

The above objects and other advantages of the present invention will become more apparent by describing in detail preferred embodiments thereof with reference to the attached drawings in which:

FIGS. 1A to 1D are sectional views showing methods of forming metallic thin films using an atomic layer deposition process according to one embodiment of the present invention.

FIG. 2 is a graph showing the structure of the thin film of FIG. 1D analyzed by using an X-ray diffraction (XRD) system according to one embodiment of the present invention.

FIG. 3 is a graph showing the specific resistance of a thin film when H₂ is used as a reducing gas in a conventional process.

FIG. 4 is a sectional view showing a TaN thin film according to an embodiment of the present invention.

FIG. 5 is a sectional view showing a metal layer according to one embodiment of the present invention.

### DETAILED DESCRIPTION OF PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. Moreover, each embodiment described and illustrated herein includes its complementary conductivity type embodiment as well.

A brief description of methods according to embodiments of the present invention will now be described. Firstly, a metallic precursor is introduced onto a substrate. The metallic precursor includes a metal element and bonded elements as reactants. The bonded elements are chemically bonded to the metal element and a part of the bonded element includes a ligand-bonded element, which is ligand-bonded to the metal element. The reactants are introduced onto a substrate that is placed in a chamber. The metal element of the reactants includes Ta. The metallic precursor, which is a reactant having Ta, includes a metallorganic precursor or a tantalum halide precursor. In detail, the metallorganic precursor includes a tantalum amine derivative, such as terbutylimido-tris-diethylamido-tantalum ((NEt₂)₃Ta═Nbu^{t}), Ta(NR)(NR₂R₃) 3, (wherein, R₁, R₂, and R₃ are H or C₁-C₆ alkyl-radicals and are the same or different from each other), Ta(NR₁R₂)₅, (wherein, R₁ and R₂, are H or C₁-C₆ alkyl-radicals and are the same or different from each other), Ta(NR₁ R₂) ₓ(NR₃R₄)₅₋ₓ, (wherein, R₁, R₂, R₃ and R₄ are H or C₁-C₆ alkyl-radicals and are the same or different from each other), or tertiaryamylimido-tris-diethylamido-tantalum (Ta(═NC(CH₃)₂C₂H₅)(N(CH₃) 2) 3). Examples of tantalum halide precursors are TaF₅, TaCI₅, TaBr₅, or Tal₅.

At this time, the reactants are introduced in a gaseous state. Some of the reactants are chemisorbed (chemically absorbed) on the substrate, and the remaining reactants are physisorbed (physically absorbed on the substrate). The non-chemisorbed reactants are removed from the substrate. At this time, the removal of the reactants is achieved through a ligand-exchange between ligand-bonded elements or a deposition caused by the ligand-exchange.

The physisorbed reactants, that are the non-chemisorbed reactants, are removed using an inert gas. Preferably, Ar or N₂ is used as an inert gas. Then, a metal-containing solid is formed on the substrate by removing the ligand-bonded elements from the chemisorbed reactant. The ligand-bonded elements are removed by using H₂, NH₃, SiH₄, or Si₂H₆, for example, alone or in combination. These compounds are preferably activated through a remote plasma process that avoids damage to the substrate.

The atomic layer deposition is carried out at a constant pressure in the range between about 0.3 Torr and about 10 Torr. More preferably, the atomic layer deposition is carried out at a pressure in a range between about 0.3 Torr and about 5 Torr. In addition, the atomic layer deposition is carried out at a temperature below about 650° C. When the ligand-bonded elements are activated, the thin film can be formed at a temperature below 300° C. using an atomic layer deposition technique. A TaN thin film is formed by repeatedly carrying out the atomic layer deposition technique. Thus, a TaN thin film may be formed as a barrier metal layer for a copper metal layer.

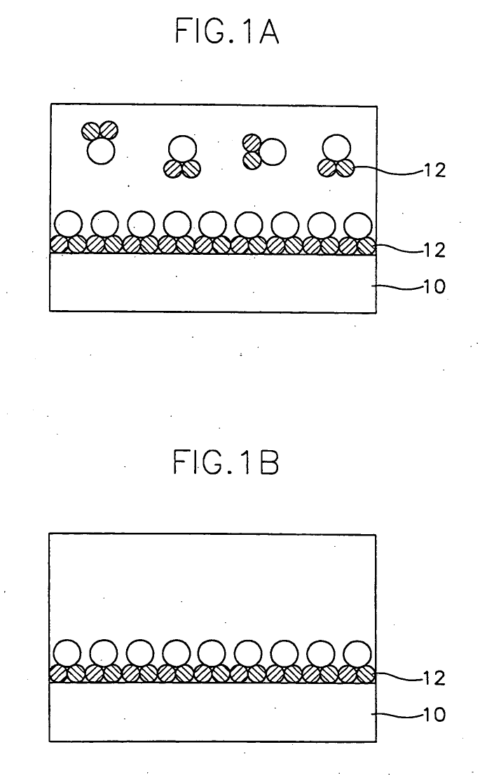

Hereinafter, methods for depositing atomic layers will be described with reference to the accompanying drawings. In particular, FIGS. 1A to 1D are sectional views showing methods for depositing an atomic metal layer. Firstly, a substrate 10 including silicon is placed in a process chamber. Then, the chamber is maintained at a pressure in a range from between about 0.3 Torr and about 10 Torr. In addition, the substrate 10 is heated to a temperature of less than about 650° C. TBTDET then is introduced onto the substrate 10 as reactants 12. As a result, a quantity of the reactants 12 is chemisorbed on the substrate 10.

Referring to FIG. 1B, an inert gas is introduced onto the substrate. As a result, the non-chemisorbed reactants 12 are removed from the substrate 10. Referring to FIG. 1C, a removal gas, which is any one selected from the group consisting of H₂, NH₃, SiH₄, Si₂H₆, or combinations thereof is introduced onto the substrate 10. Referring to FIG. 1D, ligand-bonded elements 12a, included in the bonding elements of the chemisorbed reactants, are removed by the removal gas. The removal of the ligand-bonded elements 12a can be carried out by a ligand exchange between the ligand bonded elements 12. Accordingly, an atomic metal layer 14 comprising TaN is deposited on the substrate 10.

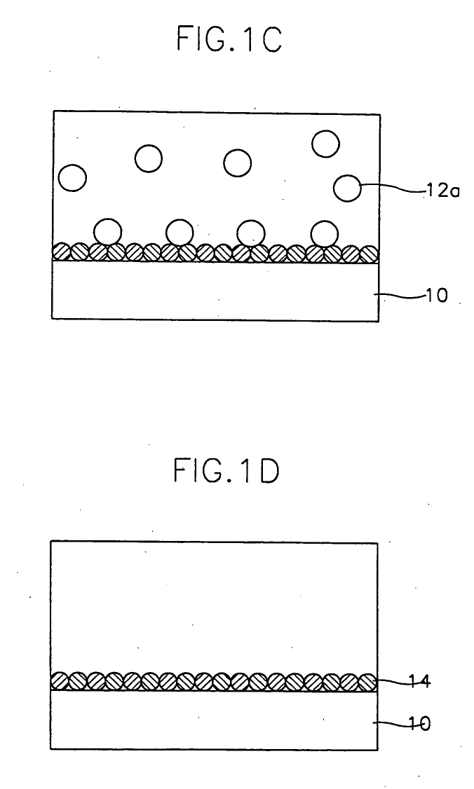

FIG. 2 is a graph showing the structure of the thin film analyzed using an XRD technique according to one embodiment of the present invention. It is understood from FIG. 2 that if the atomic layer deposition is carried out using one of NH₃, SiH₄ or a combination thereof as a removal gas, the TaN layer will typically have a crystalline structure. The graph shown in FIG. 2 was obtained under the process condition, in which the substrate 10 was heated at a temperature about 400° C. during the deposition process.

In FIG. 2, whenever NH₃ was used as a removal gas (B), or SiH₄ was used as a removal gas (A), or a combination thereof was used as removal gas (C), a TaN peak (111) was detected. It is understood from the graph of FIG. 2 that TaN is included in the atomic layer.

The reaction mechanism of the atomic layer deposition of TaN is as follows. (Net₂)₃Ta═Nbu^{t} is chemisorbed on the substrate as the reactants. Then, the non-chemisorbed reactants are removed by an inert gas. The removal of the reactants is a purging process. Thereafter, a removal gas, which is any one selected from the group consisting of H₂, NH₃, SiH₄, Si₂H₆, or combinations thereof, is introduced onto the substrate. Then, the ligand-bonded elements in the (Net₂)₃Ta—Nbu^{t}are removed by the removal gas because the reactive force of the removal gas with respect to the ligand bonded elements is greater than the bonding force between ligand bonding elements. In addition, since Ta═N has a double bonding structure, the bonding between Ta and N is not affected by the removal gas. Therefore, by removing the ligand bonded elements, the atomic layer including Ta═N is deposited on the substrate.

The reactant ((Net₂)₃Ta═Nbu^{t}) is typically decomposed at a temperature of 650° C. or higher. For this reason, the atomic layer deposition techniques described herein should not be conducted at a temperature above 650° C. In addition, if the temperature is below 300° C., the reactants typically are not decomposed at all. Accordingly, the removal gas is activated and then used. Preferably, the activation is carried out through a remote plasma process to protect the substrate. In addition, if the temperature is in the range of 300 to 650° C., the reactant is partially decomposed.

Therefore, if the activated removal gas is used, the removal of the bonding elements is easily carried out when depositing the atomic layer under the above temperature range.

The method for forming the thin film using the atomic layer deposition process can achieve a thin film having low specific resistance. Particularly, since the method uses a removal gas that is activated through the remote plasma process, the process parameters caused by the plasma are excluded. Accordingly, an atomic layer having a low specific resistance and superior step coverage can be achieved in a simplified process at a lower temperature. Hereinafter, examples of embodiments of the present invention will be described. However, the present invention is not limited by the following examples:

### EXAMPLE 1

After loading the substrate into a chamber, the pressure in the chamber was adjusted to a pressure of 5 Torr. In addition, the substrate was heated at a temperature of 450° C. Then, terbutylimido-tris-diethylamido tantalum was introduced into the chamber having the above pressure and the temperature at a flow rate of 10 g/min. A part of terbutylimido-tris-diethylamido tantalum was chemisorbed on the substrate. The non-chemisorbed reactants were removed from the chamber by using nitrogen as an inert gas. Then, 100 sccm of NH₃, activated through the remote plasma process, was introduced into the chamber so as to remove the ligand bonded elements from the chemisorbed reactant. As a result, the thin film of the atomic layer including TaN was formed on the substrate. The XRD analysis was carried out with respect to the obtained thin film. As a result, as shown in FIG. 2, the peak having a (111) direction was observed and the specific resistance value thereof was 1,254 μΩcm.

### EXAMPLE 2

The thin film of the atomic layer including TaN was formed in the same manner as in Example 1, except that the substrate was heated at the temperature of 500° C. The specific resistance of the obtained TaN layer was 1,035 μΩcm. In addition, the XRD analysis was carried out with respect to the thin film. As a result, the peak having a (111) direction as shown in FIG. 2 was observed.

### EXAMPLE 3

The thin film of the atomic layer including TaN was formed in the same manner as in Example 1, except that the substrate was heated at the temperature of 550° C. The specific resistance of the obtained TaN layer was 1117 μΩcm. In addition, the XRD analysis was carried out with respect to the thin film. As a result, the peak having a (111) direction as shown in FIG. 2 was observed.

### EXAMPLE 4

The thin film of the atomic layer including TaN was formed in the same manner as in Example 1, except that the substrate was heated at the temperature of 600° C. The specific resistance of the obtained TaN layer was 721 μΩcm. In addition, the XRD analysis was carried out with respect to the thin film. As a result, the peak having a (111) direction as shown in FIG. 2 was observed.

### EXAMPLE 5

After loading the substrate in the chamber, the pressure in the chamber was adjusted to a pressure of 0.3 Torr. In addition, the substrate was heated at the temperature of 500° C. Then, terbutylimido-tris-diethylamido tantalum was introduced into the chamber having the above pressure and the temperature at the flow rate of 10 g/min. A part of terbutylimido-tris-diethylamido tantalum was chemisorbed on the substrate. The non-chemisorbed reactants were removed from the chamber by using nitrogen as an inert gas. Then, 500 sccm of NH₃ activated through the remote plasma process was introduced into the chamber, so as to remove the ligand bonded elements from the chemisorbed reactants. As a result, the thin film of the atomic layer including TaN was formed on the substrate. The XRD analysis was carried out with respect to the obtained thin film. As a result, the peak having a (11) direction as shown in FIG. 2 was observed and the specific resistance value thereof was 1,744 μΩcm.

### EXAMPLE 6

The thin film of the atomic layer including TaN was formed in the same manner as in Example 5, except that the substrate was heated at the temperature of 550° C. The specific resistance of the obtained TaN layer was 1,301 μΩcm. In addition, the XRD analysis was carried out with respect to the thin film. As a result, the peak having (111) direction as shown in FIG. 2 was observed.

### EXAMPLE 7

The thin film of the atomic layer including TaN was formed in the same manner as in Example 5, except that the substrate was heated at the temperature of 600° C. The specific resistance of the obtained TaN layer was 1,304 μΩcm. In addition, the XRD analysis was carried out with respect to the thin film. As a result, the peak having (111) direction as shown in FIG. 2 was observed.

### EXAMPLE 8

After loading the substrate in the chamber, the pressure in the chamber was adjusted to a pressure of 5 Torr. In addition, the substrate was heated at the temperature of 400° C. Then, terbutylimido-tris-diethylamido tantalum was introduced into the chamber having the above pressure and the temperature at a flow rate of 10 g/min. A part of terbutylimido-tris-diethylamido tantalum was chemisorbed on the substrate. The non-chemisorbed reactants were removed from the chamber by using nitrogen as an inert gas. Then, 500 sccm of NH₃ activated through the remote plasma process was introduced into the chamber, so as to remove the ligand bonded elements from the chemisorbed reactant. As a result, the thin film of the atomic layer including TaN was formed on the substrate. The XRD analysis was carried out with respect to the obtained thin film. As a result, the peak having a (111) direction as shown in FIG. 2 was observed and the specific resistance value thereof was 924.5 μΩcm.

### EXAMPLE 9

The thin film of the atomic layer including TaN was formed in the same manner as in Example 8, except that the substrate was heated at a temperature of 450° C. The specific resistance of the obtained TaN layer was 6851 μΩcm. In addition, the XRD analysis was carried out with respect to the thin film. As a result, the peak having a (111) direction as shown in FIG. 2 was observed.

### EXAMPLE 10

After loading the substrate in the chamber, the pressure in the chamber was adjusted to a pressure of 1 Torr. In addition, the substrate was heated at a temperature of 250° C. Then, tertiaryamylimido-tris-diethylamido-tantalum was introduced into the chamber having the above pressure and the temperature at a flow rate of 10 g/min. A part of tertiaryamylimido-tris-diethylamido-tantalum was chemisorbed on the substrate. The non-chemisorbed reactants were removed from the chamber by using nitrogen as an inert gas. Then, 500 sccm of NH 3 activated through the remote plasma process was introduced into the chamber, so as to remove the ligand bonded elements from the chemisorbed reactant. As a result, the thin film of the atomic layer including TaN was formed on the substrate. The XRD analysis was carried out with respect to the obtained thin film. As a result, the peak having a (111) direction as shown in FIG. 2 was observed.

### Comparative Example

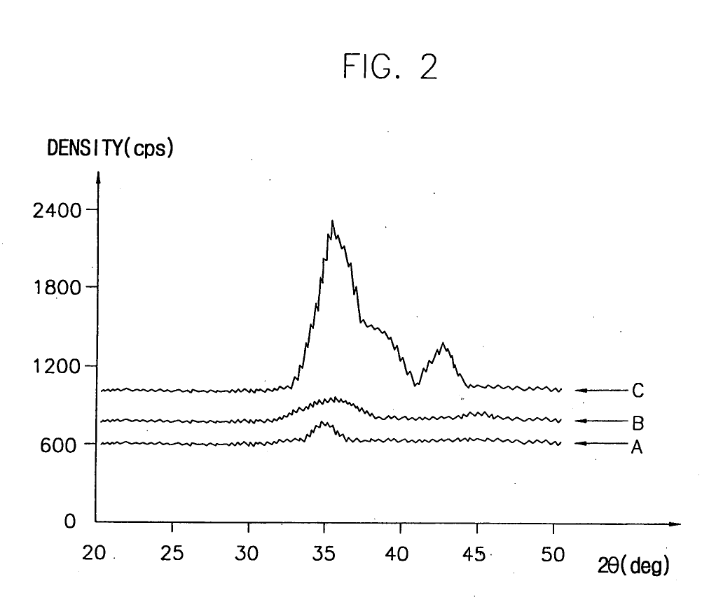

As disclosed in the Kang et al. article, a thin film can be formed using H₂ as reducing gas. The deposition process of Kang et al. was carried out as follows. The chamber pressure was adjusted to a pressure of 0.3 Torr and the substrate was heated at a temperature of 400° C. Then, terbutylimido-tris-diethylamido tantalum was introduced into the chamber at a flow rate of 10 g/min and 500 sccm of NH₃ was introduced into the chamber. The thin film formed under the above condition represents the result as shown in FIG. 3. That is, as the flow rate of H₂ was increased, the specific resistance of the thin film was also increased.

Hereinafter, additional methods for forming TaN thin films will be described The TaN thin film is formed under the same process conditions that were described above with respect to the atomic layer deposition process. At this time, a process for removing the non-chemisorbed reactants using an inert gas, and a process for removing the ligand bonded elements using a gas selected from the group consisting of H₂, NH₃, SiH₄, Si₂H₆, or combinations thereof can be repeatedly carried out for completely removing impurities remaining in the TaN film. In addition, the TaN thin film is formed by repeatedly carrying out the atomic layer deposition process. That is, by repeatedly depositing the atomic layer, the TaN thin film of the atomic layer having a predetermined thickness is obtained. The thickness of the thin film is varied depending on the number of the processes to be repeated. Therefore, the thickness of the thin film can be precisely controlled by adjusting the number of processes to be repeated. In addition, since the thin film is formed through the atomic layer deposition process, the thin film has superior step coverage. Besides, a post treatment process for the TaN film can be carried out by using any one selected from the group consisting of H₂, NH₃, SiH₄, Si₂H₆, or combinations thereof, which are activated through the remote plasma process, after forming the TaN film in order to completely remove the impurities remaining in the TaN film.

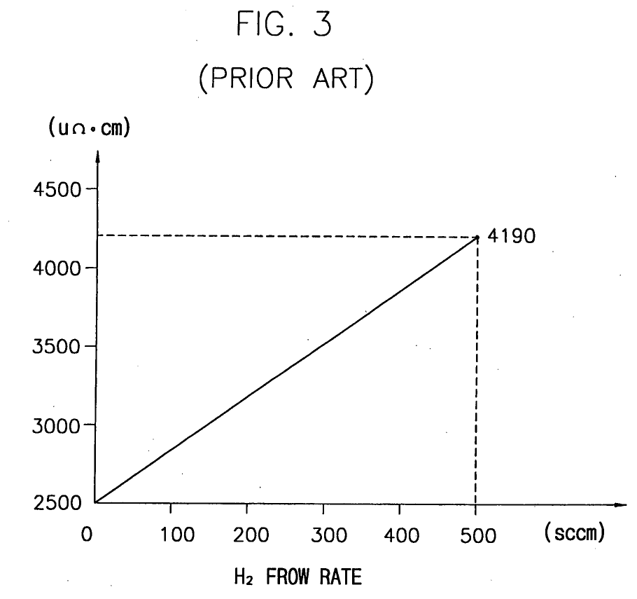

In one additional embodiment, a substrate formed with an insulating pattern having an opening is loaded in the chamber. Then, the TaN-containing atomic layer is deposited on the substrate in the same manner as the atomic layer deposition process. At this time, the atomic layer is continuously formed on the surface of the substrate, the insulating layer and the sidewall of the opening. Then, the atomic layer deposition process is repeatedly carried out. As a result, as shown in FIG. 4, the TaN thin film 44 is continuously formed on the surface of the substrate 40, the insulating layer 42 and the sidewall of the opening.

In addition, the TaN thin film can be applicable not only to the substrate formed with the insulating layer pattern having the opening, but also to a multi-layer wiring structure formed on the substrate. Hereinafter, a method for forming a wiring layer including the TaN film will be described. Firstly, the substrate formed with the insulating layer pattern having the opening is loaded into the chamber. The opening has an aspect ratio of 11:1. Then, the pressure in the periphery of the substrate is adjusted to a pressure of 0.3 Torr. In addition, the substrate is heated at a temperature of 450° C. Then, as the reactants, terbutylimido-tris-diethylamido tantalum is introduced into the chamber at a flow rate of 10 g/min. Accordingly, a part of terbutylimido-tris-diethylamido tantalum is chemisorbed on the substrate. Then, an inert gas, such as Ar, is introduced into the chamber at a flow rate of 100 sccm, thereby removing the non-chemisorbed reactant from the substrate. Then, 500 sccm of NH₃ and 100 sccm of SiH₄ which are activated through the remote plasma process, are introduced into the chamber, so as to remove the ligand bonded elements from the chemisorbed reactant. As a result, the TaN-containing atomic layer is deposited on the substrate. At this time, a process for removing the non-chemisorbed reactants by using an inert gas, and a process for removing the ligand bonding elements by using NH₃ and SiH₄ can be repeatedly carried out for completely removing impurities remaining in the TaN film. Then, the reactant, inert gas and removal gas are repeatedly performed (e.g., about 600 times) under the above process conditions. As a result, the atomic layer is continuously deposited so that the TaN thin film is continuously formed on the sidewall of the opening, the insulating layer and the surface of the substrate exposed at a lower portion of the opening. A post treatment process for the TaN film can be carried out by using any one of the gases selected from the group consisting of H₂, NH₃, SiH₄, Si₂H₆, or combinations thereof, which are activated through the remote plasma process, after forming the TaN film in order to completely remove the impurities remaining in the TaN film.

Since the TaN thin film is formed through the atomic layer deposition process, the obtained TaN thin film has superior step coverage. In addition, the process can be carried out at a lower temperature. Further, the atomic layer deposition is carried out through the remote plasma process to protect the substrate, and the TaN thin film can be formed using simple process parameters. The TaN thin film can be used as the barrier metal layer of the metal layer. Particularly, it is preferably applicable for forming a barrier metal layer in combination with a copper metal layer.

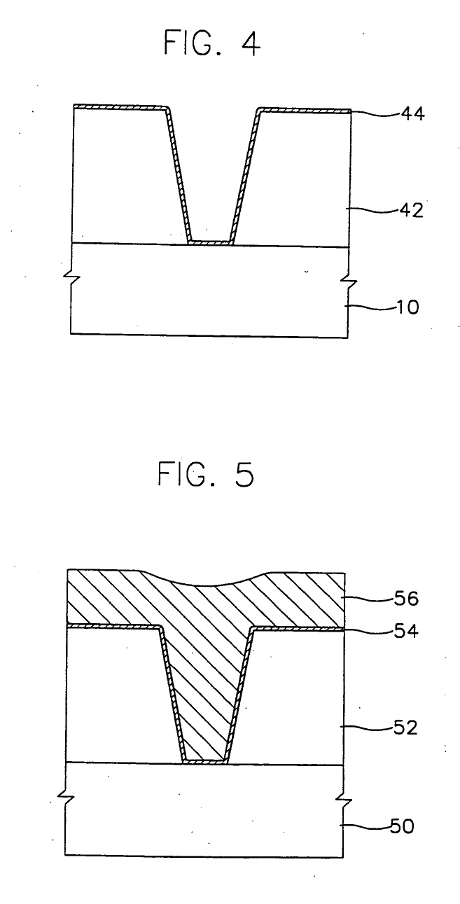

In detail, the TaN thin film is formed on the insulating pattern using an atomic layer deposition process. Accordingly, as shown in FIG. 5, the TaN thin film 54 is continuously formed on the substrate 50, the sidewall of the opening and on the pattern of the insulating layer 52. Then, a copper metal layer 56 is formed on the TaN thin film 54. The copper metal layer 56 is mainly formed by means of a conventional thin film forming process. Accordingly, the TaN thin film is easily formed as the barrier metal layer that is suitable for use with a copper metal layer. Therefore, the characteristics of copper can be sustained.

In addition, the above method can be used to form a thin film including Al, Ru, or Si. As described above, according to the present invention, the atomic layer including the metal element having a low specific resistance can be easily formed at a relatively low temperature. In addition, the atomic layer deposition process has a simple process parameter. Therefore, the atomic layer deposition can be easily carried out because the gas used for depositing the atomic layer is activated through a remote plasma process. Since the method of the present invention has the simple process parameter, besides the advantage of the atomic layer deposition itself, the atomic layer deposition process according to the present invention can be applicable to form a thin film.

While the present invention has been described in detail with reference to the preferred embodiments thereof, it should be understood to those skilled in the art that various changes, substitutions and alterations can be made hereto without departing from the scope of the invention as defined by the appended claims.

What is claimed is:

1. A method for depositing an atomic layer, the method comprising the steps of:
a) introducing a metallorganic precursor onto a substrate, the metallorganic precursor including a metal element and bonding elements as reactants, the bonding elements being chemically bonded to the metal element, a part of the bonding elements including a ligand bonding element which is ligand-bonded to the metal element;
b) chemisorbing a part of the reactants on the substrate;
c) removing non-chemisorbed reactants from the substrate; and
d) removing the ligand bonded element of the bonded elements from the chemisorbed reactants, thereby forming a metal-containing solid on the substrate.

2. The method of claim 1, wherein the metal element included in the reactant is Ta.

3. The method of claim 1, wherein the reactants include a metallorganic precursor or tantalum halide precursor.

4. The method of claim 3, wherein the metallorganic precursor is a tantalum amine derivative.

5. The method of claim 4, wherein the tantalum amine derivative includes terbutylimido-tris-diethylamido-tantalum ((NEt₂)₃Ta═Nbu^{t}), Ta(NR₁)(NR₂R₃)₃, (wherein, R₁, R₂ and R₃ are H or C₁-C₆ alkyl-radical and are the same or different from each other), Ta(NR₁R₂)₅, (wherein, R₁ and R₂, are H or C₁-C₆ alkyl-radical and are the same or different from each other), Ta(NR₁ R₂)ₓ(NR₃R₄)₅₋ₓ, (wherein, R₁, R₂, R₃ and R₄ are H or C₁-C₆ alkyl-radical and are the same or different from each other), or tertiaryamylimido-tris-diethylamido-tantalum (Ta(═NC(CH₃)₂C₂H₅)(N(CH₃)₂)₃).

6. The method of claim 3, wherein the tantalum halide precursor is at least any one selected from the group consisting of TaF₅, TaCl₅, TaBr₅, and Tal₅.

7. The method of claim 1, wherein the reactants are introduced in a gaseous state.

8. The method of claim 1, wherein the non-chemisorbed reactants are removed by using an inert gas.

9. The method of claim 8, wherein the inert gas includes Ar or N₂.

10. The method of claim 1, wherein the ligand-bonded element is removed by using any one selected from the group consisting of H₂, NH₃, SiH₄, Si₂H₆, and combinations thereof.

11. The method of claim 1, wherein the ligand-bonded element is removed by using an activated gas selected from the group consisting of H₂, NH₃, SiH₄, Si₂H₆, and combinations thereof.

12. The method of claim 11, wherein the activated gas is prepared through a remote plasma process.

13. The method of claim 1, wherein the solid is TaN.

14. The method of claim 1, wherein steps a) to d) are carried out at a temperature no more than 650° C.

15. The method of claim 1, wherein steps a) to d) are carried out at a constant pressure in a range of 0.3 to 10 Torr.

16. A method for forming a thin film by atomic layer deposition, the method comprising the steps of:
a) introducing gaseous tantalum amine derivative or tantalum halide precursor as reactants onto a substrate;
b) chemisorbing a part of the reactants on the substrate;
c) introducing an inert gas onto the substrate to remove non-chemisorbed reactants from the substrate;
d) introducing any one gas selected from the group consisting of H₂, NH₃, SiH₄, Si₂H₆ and combinations thereof onto the substrate to remove a ligand-bonded element from the chemisorbed reactants, thereby forming a TaN-containing solid on the substrate; and
e) repeating steps a) to d) in sequence at least once to form a TaN thin film including the TaN-containing solid.

17. The method of claim 16, wherein the tantalum amine derivative includes terbutylimido-tris-diethylamido-tantalum ((NEt₂)₃Ta═Nbu^{t}), Ta(NR₁)(NR₂R₃)₃, (wherein, R₁, R₂, and R₃ are H or C₁-C₆ alkyl-radical and are the same or different from each other), Ta(NR₁ R₂)₅, (wherein, R₁ and R₂, are H or C₁-C₆ alkyl-radical and are the same or different from each other), Ta(NR₁ R₂)ₓ(NR₃R₄)₅₋ₓ, (wherein, R₁, R₂, R₃ and R₄ are H or C₁-C₆ alkyl-radical and are the same or different from each other), or tertiaryamylimido-tris-diethylamido-tantalum (Ta(═NC(CH₃)₂C₂H₅)(N(CH₃)₂)₃).

18. The method of claim 16, wherein the tantalum halide precursor includes TaF₅, TaCI₅, TaBr₅, or Tal₅.

19. The method of claim 16, wherein the gases H₂, NH₃, SiH₄, or Si₂H₆, or combinations thereof, are activated through a remote plasma process.

20. The method of claim 16, wherein steps a) to d) are carried out at a temperature no more than 650° C.

21. The method of claim 16, wherein steps a) to d) are carried out at a constant pressure in a range of 0.3 to 10 Torr.

22. The method of claim 16, wherein, before carrying out step e), steps c) and d) are repeated at least once.

23. The method of claim 16, wherein, after carrying out step e), a post treatment process for the TaN film is carried out by using any one selected from the group consisting of H₂, NH₃, SiH₄, Si₂H₆, and a combination thereof, which are activated through a remote plasma process.

24. A method for forming a thin film by using an atomic layer deposition, the method comprising the steps of:
a) forming an insulating layer on a substrate;
b) etching a predetermined portion of the insulating layer to form an opening for exposing a surface portion of the substrate;
c) continuously introducing gaseous tantalum amine derivative or tantalum halide precursor as reactants onto the surface portion of the substrate, the insulating layer and a sidewall of the opening;
d) continuously chemisorbing a part of the reactants on the surface portion of the substrate, the insulating layer and a sidewall of the opening;
e) continuously introducing an inert gas onto the surface portion of the substrate, the insulating layer and a sidewall of the opening to remove the non-chemisorbed reactants from the surface portion of the substrate, the insulating layer and a sidewall of the opening;
f) introducing any one selected from the group consisting of H₂, NH₃, SiH₄, Si₂H₆, and a combination thereof onto the surface portion of the substrate, the insulating layer and the sidewall of the opening so as to remove a ligand bonded element from the chemisorbed reactants, there by forming a TaN-containing solid; and
g) repeating steps c) to f) at least once to continuously form a TaN thin film from the TaN-containing solid on the surface of the substrate, the insulating layer and the sidewall of the opening.

25. The method of claim 24, wherein the tantalum amine derivative includes terbutylimido-tris-diethylamido-tantalum ((NEt₂)₃Ta═Nbu^{t}), Ta(NR₁)(NR₂R₃)₃, (wherein, R₁, R₂, and R₃ are H or C₁-C₆ alkyl-radical and are the same or different from each other), Ta(NR₁R₂)₅, (wherein, R₁ and R₂, are H or C₁-C₆ alkyl-radical and are the same or different from each other), Ta(NR₁ R₂) (NR₃R₄) 1-x, (wherein, R₁, R₂, R₃ and R₄ are H or C₁-C₆ alkyl-radical and are the same or different from each other), or tertiaryamylimido-tris-diethylamido-tantalum (Ta(═NC(CH₃)₂C₂H₅)(N(CH₃)₂)₃).

26. The method of claim 24, wherein the tantalum halide precursor includes TaF₅, TaCI₅, TaBr₅, or Tal₅.

27. The method of claim 24, wherein the insulating layer is a thin film including oxide material, and NH₃, SiH₄, Si₂H₆, and a combination thereof are activated through a remote plasma process.

28. The method of claim 24, wherein, before carrying out step g), steps e) and f) are repeated at least once.

29. The method of claim 24, wherein, after carrying out step g), a post treatment process for the TaN film is carried out by using any one selected from the group consisting of H₂, NH₃, SiH₄, Si₂H₆, and a combination thereof, which are activated through a remote plasma process.

30. A method for forming a metal layer, the method comprising the steps of:
a) forming an insulating layer on a lower structure formed on the substrate;
b) forming an opening for exposing a surface portion of the lower structure by etching a predetermined portion of the insulating layer;
c) continuously introducing gaseous tantalum amine derivative or tantalum halide precursor as reactants onto the surface portion of the lower structure, the insulating layer and a sidewall of the opening;
d) continuously chemisorbing a part of the reactants on the surface portion of the lower structure, the insulating layer and the sidewall of the opening;
e) removing non-chemisorbed reactants from the surface of the lower structure, the insulating layer and the sidewall of the opening by continuously introducing an inert gas onto the surface portion of the lower structure, the insulating layer, and the sidewall of the opening;
f) introducing any one selected from the group consisting of H₂, NH₃, SiH₄, Si₂H₆, and a combination thereof onto the surface portion of the substrate, the insulating layer and the sidewall of the opening so as to remove a ligand-bonded element from the chemisorbed reactants, thereby forming a TaN-containing solid;
g) repeating steps c) to f) at least once to continuously form a TaN thin film from the TaN containing solid on the lower structure, the insulating layer and the sidewall of the opening; and
h) forming a metal layer including the metal on the TaN thin film filling, the metal layer filling up the opening.

31. The method of claim 30, wherein the tantalum amine derivative includes terbutylimido-tris-diethylamido-tantalum ((NEt₂)₃Ta═Nbu^{t}), Ta(NR₁)(NR₂R₃)₃, (wherein, R₁, R₂ and R₃ are H or C₁-C₆ alkyl-radical and are the same or different from each other), Ta(NR₁R₂)₅, (wherein, R₁ and R₂, are H or C₁-C₆ alkyl-radical and are the same or different from each other), Ta(NR₁ R₂)ₓ(R₃R₄)₅₋ₓ, (wherein, R₁, R₂, R₃ and R₄ are H or C₁-C₆ alkyl-radical and are the same or different from each other), or tertiaryamylimido-tris-diethylamido-tantalum (Ta(═NC(CH₃)₂C₂H₅)(N(CH₃)₂)₃).

32. The method of claim 30, wherein the tantalum halide precursor includes TaF₅, TaCI₅, TaBr₅, or Tal₅.

33. The method of claim 30, wherein the metal layer is comprised of any one selected from the group consisting of Cu, Al, Ru and Si, and H₂, NH₃, SiH₄, Si₂H₆, and a combination thereof, which are activated through a remote plasma process.

34. The method as claimed in claim 30, wherein, before carrying out step g), steps e) and f) are repeated at least once.

35. The method of claim 30, wherein, between steps g) and h), a post treatment process for the TaN film is carried out by using any one selected from the group consisting of H₂, NH₃, SiH₄, Si₂H₆, and a combination thereof, which are activated through a remote plasma process.
